(19) United States
(12) Patent Application Publication
(10) Pub. No.: US 2025/0038074 A1
(43) Pub. Date: Jan. 30, 2025

(54) SEMICONDUCTOR DEVICES WITH BACKSIDE INTERCONNECT STRUCTURE AND THROUGH VIA STRUCTURE

(71) Applicant: Taiwan Semiconductor Manufacturing Company, Ltd., Hsin-Chu (TW)

(72) Inventors: Tsung-Chieh Hsiao, Changhua County (TW); Yi Ling Liu, Hsinchu City (TW); Yun-Sheng Li, Hsinchu (TW); Ke-Gang Wen, Hsinchu County (TW); Yu-Bey Wu, Hsinchu City (TW); Liang-Wei Wang, Hsinchu City (TW); Dian-Hau Chen, Hsinchu (TW)

(21) Appl. No.: 18/526,311

(22) Filed: Dec. 1, 2023

Related U.S. Application Data
(60) Provisional application No. 63/516,242, filed on Jul. 28, 2023.

(51) Int. Cl. H01L 23/48; H01L 21/768; H01L 23/522; H01L 23/528

(52) U.S. Cl. CPC H01L 23/481; H01L 21/76877; H01L 23/5226; H01L 23/5283

(57) ABSTRACT

A method includes forming a first multilayer interconnect structure over a first side of a device layer, forming a first portion of a second multilayer interconnect structure under a second side of the device layer, forming a trench that extends through the second dielectric layer, the device layer, and the first dielectric layer, forming a conductive structure in the trench, and forming a second portion of the second multilayer interconnect structure under the first portion of the second multilayer interconnect structure. The second portion of the second multilayer interconnect structure includes patterned metal layers disposed in a third dielectric layer, and wherein one or more of the patterned metal layers are in electrical connection with the conductive structure.

### PRIORITY DATA

This is a non-provisional application of and claims benefit of U.S. Provisional Patent Application Ser. No. 63/516,242, filed Jul. 28, 2023, the entire disclosure of which is incorporated herein by reference.

### BACKGROUND

The semiconductor integrated circuit (IC) industry has experienced rapid growth. Continuing advances in semiconductor manufacturing processes have resulted in integrated circuits (“ICs”) having semiconductor devices with finer features and/or higher degrees of integration. Functional density (i.e., the number of interconnected devices per IC chip area) has generally increased while feature size (i.e., the smallest component that can be created using a fabrication process) has decreased. This scaling-down process generally has generally provided benefits by increasing production efficiency and lowering associated costs.

Advanced IC packaging technologies have been developed to further reduce density and/or improve performance of ICs, which are incorporated into many electronic devices. For example, IC packaging has evolved, such that multiple ICs may be vertically stacked in so-called three-dimensional (“3D”) packages, or 2.5D packages (which use an interposer). Through via (also referred to as through-silicon via or through-substrate via (TSV)) is one technique for electrically and/or physically connecting stacked ICs. Although existing through vias have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1 is a fragmentary cross-sectional view of a semiconductor structure having frontside and backside interconnect structures and a through via, according to various aspects of the present disclosure.

FIGS. 2A, 2B, 2C, and 2D are enlarged, cross-sectional views of portions of semiconductor structure of FIG. 1, according to various aspects of the present disclosure.

FIG. 3 illustrates top views of guard rings and corresponding TSVs, in portion or entirety, that can be implemented in the semiconductor structure of FIG. 1, according to various aspects of the present disclosure.

FIGS. 4, 5, 6, 7, 8, 9, 10, and 11 are fragmentary cross-sectional views of a workpiece, in portion or entirety, at various fabrication stages of forming a TSV and a corresponding guard ring, according to various aspects of the present disclosure.

FIGS. 12, 13, 14, 15, 16, and 17 illustrate various embodiments of fragmentary diagrammatic cross-sectional views of a semiconductor arrangement, in portion or entirety, that includes the semiconductor structure of FIG. 1 attached to another semiconductor structure, according to various aspects of the present disclosure.

### DETAILED DESCRIPTION

The present disclosure relates generally to integrated circuit (IC) packaging, and more particularly, to enhanced through via structures for semiconductor devices with backside interconnect structures.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

An interconnect structure electrically couples various components (for example, transistors, resistors, capacitors, and/or inductors) fabricated on a substrate, such that the various components can operate as specified by design requirements. An interconnect structure includes a combination of dielectric layers and conductive layers configured to provide electrical signal routing. The conductive layers include via and contact features that provide vertical connections and conductive lines that provide horizontal connections. In some implementations, an interconnect structure may have multiple metal layers (or metallization layers) that are vertically interconnected by via or contact features. During operation of the IC device, the interconnect structure routes signals among the components of the IC device and/or distribute signals (for example, clock signals, voltage signals, and/or ground signals) to the components. An interconnect structure is formed in a back-end-of-the-line (BEOL) process, typically formed after the front-end-of-the-line (FEOL) process forms the active devices such as a transistor on a substrate and the middle-end-of-the-line (MEOL) process forms source/drain contact plugs and gate contact plugs.

In some implementations, there is a need to provide a vertical interconnect that extends through the interconnect structure and/or the substrate to facilitate interconnection among various device structures, such as CMOS image sensors (CISs), a three-dimensional integrated circuit (3DIC), MEMS devices, radio frequency (RF) devices, wafer-on-wafer (WoW) devices, and so on. Such a vertical interconnect may be referred to as a through-silicon or through-substrate via (TSV) as it extends through, in whole or in part, the semiconductor substrate. The term TSV in the present disclosure broadly encompasses via structures that provide direct power and/or signal routing from a frontside of the substrate and a backside of the substrate or vice versa.

A guard ring is often formed around the TSV to protect the TSV, improve TSV performance, improve TSV structural stability, shield and/or reduce TSV-induced noise that can negatively impact the signal integrity, or combinations thereof. The guard ring may be formed when forming a BEOL structure of the semiconductor device. The TSV may be formed after forming the BEOL structure, for example, by etching through a dielectric layer of the BEOL structure in an area defined by the guard ring and through the device layer to form a TSV trench and filling the TSV trench with a conductive material. Such TSV formation flow is generally compatible with semiconductor devices with a frontside interconnect structure.

Conventionally, semiconductor devices are built in a stacked-up fashion, having transistors at the lowest level and interconnect structures (contacts, vias, and metal lines) on top of the transistors to provide connectivity to the transistors. Power rails (such as metal lines for voltage sources and ground planes) are also above the transistors and may be part of the interconnect structures. As the integrated circuits continue to scale down, so do the power rails. This inevitably leads to increased voltage drop across the power rails, as well as increased power consumption of the integrated circuits. Other than power rails, signal lines may also suffer from such scaling down, such as the ever-reduced signal line pitches that inevitably leads to increased parasitic capacitance and reduced circuit speed. Therefore, although existing approaches in semiconductor fabrication have been generally adequate for their intended purposes, they have not been entirely satisfactory in all respects. One area of interest is how to form backside interconnect structure, including power rails and/or signal lines, and vias on the backside of an IC, with reduced resistance and parasitic capacitance. The implementation of a backside interconnect structure in semiconductor devices imposes new challenges on TSV formation. TSVs may extend through the device layer of the semiconductor device but could be blocked by the backside interconnect structure.

The present disclosure provides a TSV with a guard ring that includes a combination of frontside features and backside features, which are compatible with the semiconductor fabrication of devices featuring both frontside and backside interconnect structures. Details of the proposed TSV structure and fabrication thereof are described herein in the following pages. Different embodiments may have different advantages, and no particular advantage is required of any embodiment.

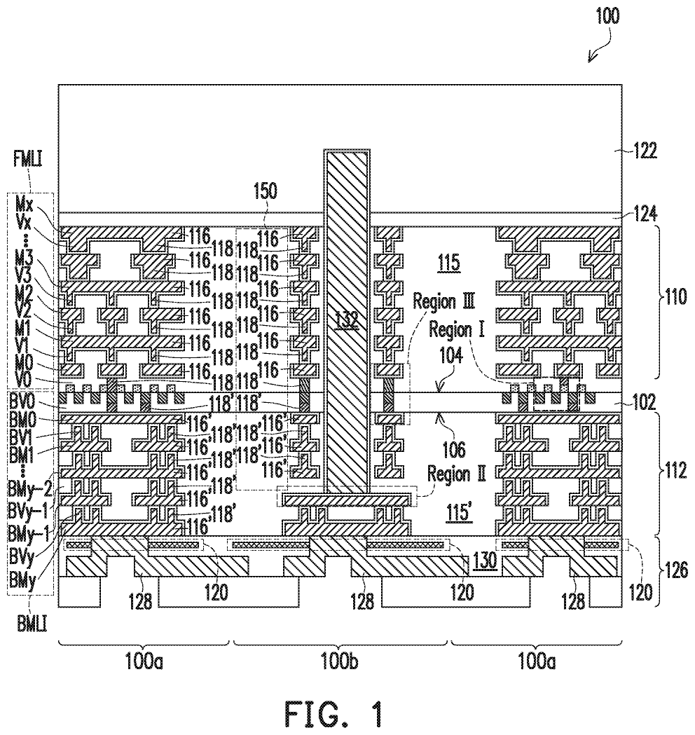

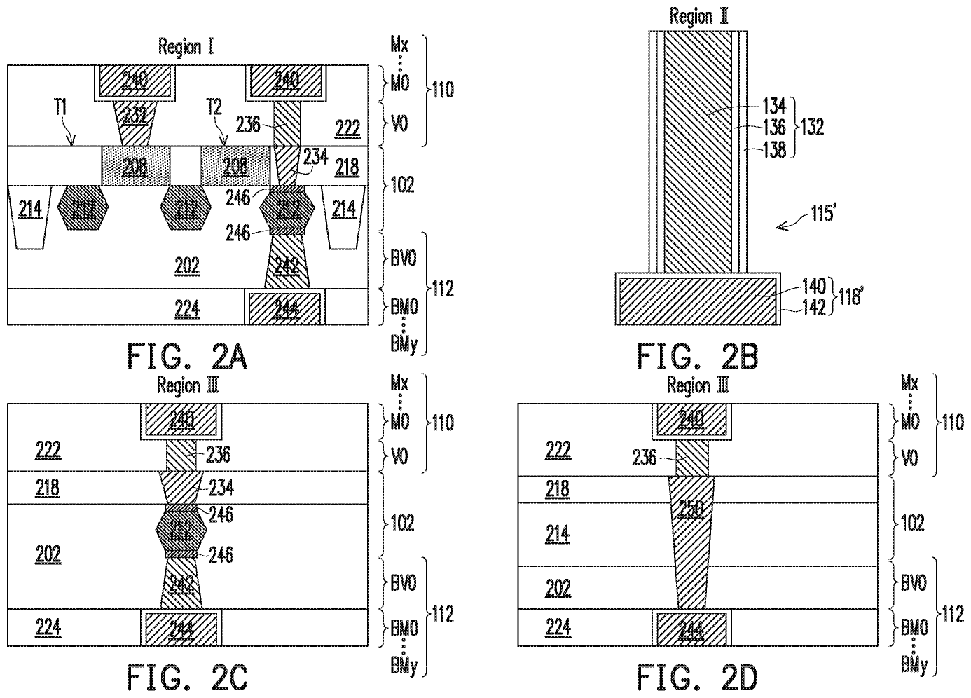

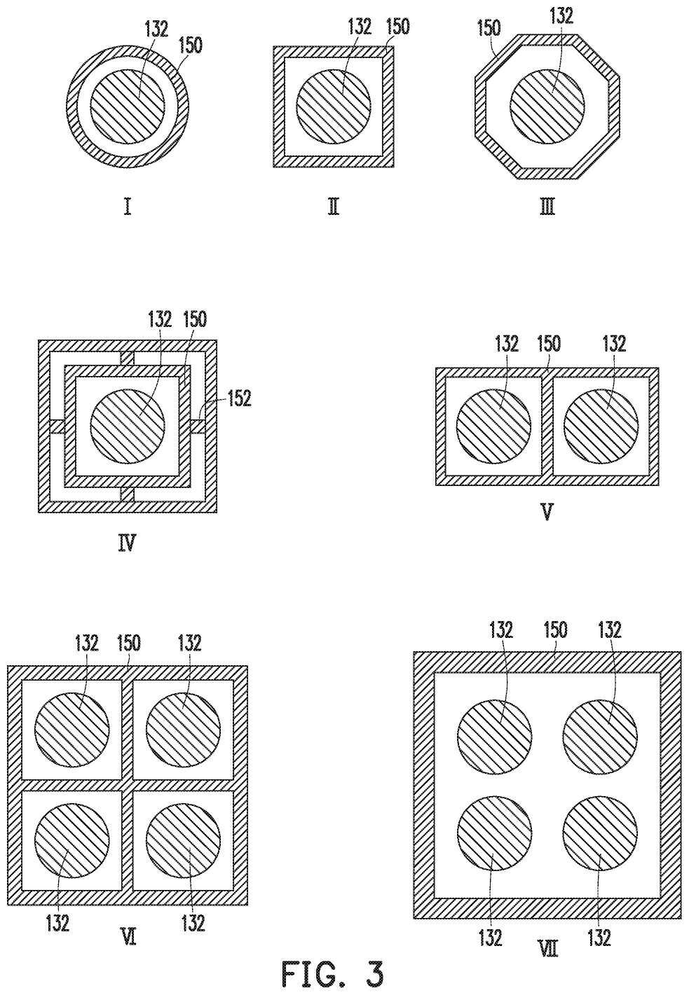

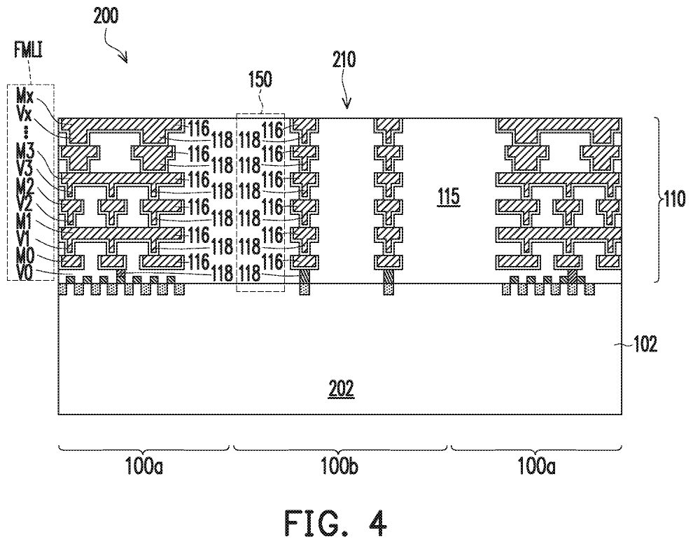

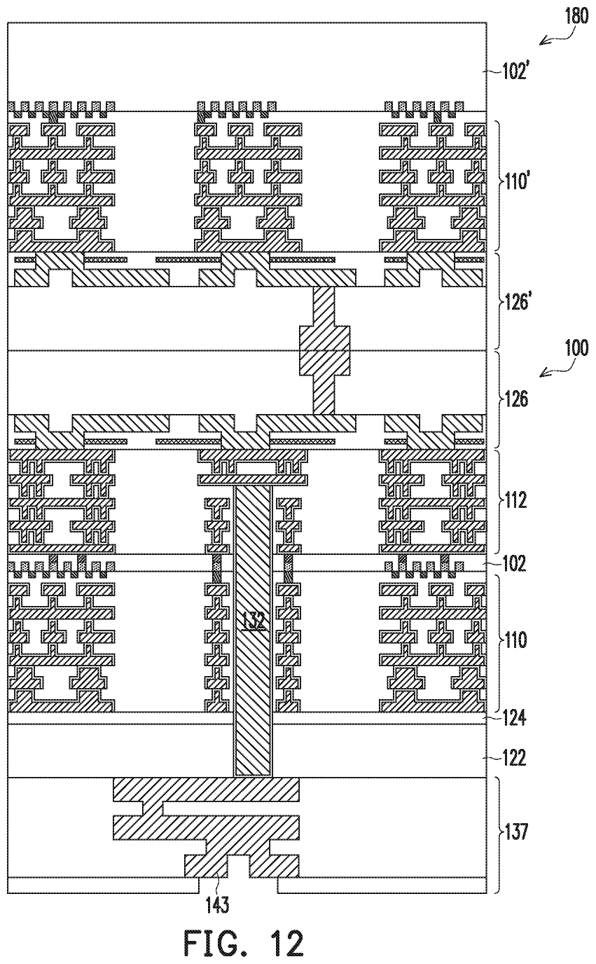

FIG. 1 is a fragmentary cross-sectional view of a semiconductor structure 100 having an improved TSV design, in portion or entirety, according to various aspects of the present disclosure. FIGS. 2A, 2B, 2C, and FIG. 2D are enlarged, cross-sectional views of portions of semiconductor structure 100 of FIG. 1 according to various aspects of the present disclosure. FIG. 3 is a top view of guard rings and corresponding TSVs, in portion or entirety, that can be implemented in semiconductor structure 100 of FIG. 1 according to various aspects of the present disclosure. FIGS. 4-11 are fragmentary cross-sectional views of a workpiece at various fabrication stages of forming the semiconductor structure 100 of FIG. 1, in portion or entirety, according to various aspects of the present disclosure. FIGS. 12-17 are fragmentary cross-sectional views of various semiconductor arrangements of stacked ICs, in portion or entirety, that include semiconductor structure 100 of FIG. 1 according to various aspects of the present disclosure.

FIG. 1 and FIGS. 2A-2D are discussed concurrently herein for ease of description and understanding. FIG. 2A is an enlarged view of a region I of the semiconductor structure 100 of FIG. 1, which includes multiple transistors formed in a device layer. FIG. 2B is an enlarged view of a region II of the semiconductor structure 100 of FIG. 1, which includes a TSV and a backside top metal feature. FIG. 2C is an enlarged view of a region III of the semiconductor structure 100 of FIG. 1, which is in an active region in which a source/drain feature adjoins the frontside features and backside features of the guard ring. An active region refers to the area where a source region, a drain region, and a channel region of the transistor are formed. An active region is also referred to as an “oxide-definition (OD) region” in the context. FIG. 2D is an enlarged view of the region III of the semiconductor structure 100 of FIG. 1 in an alternative embodiment, which is in an isolation region (e.g., a shallow trench isolation (STI) region) in which a via traveling through the isolation region adjoins the frontside features and backside features of the guard ring. FIGS. 1 and 2A-2D have been simplified for the sake of clarity to better understand the inventive concepts of the present disclosure. Additional features can be added in semiconductor structure 100, and some of the features described below can be replaced, modified, or eliminated in other embodiments of semiconductor structure 100.

In FIG. 1, the semiconductor structure 100 includes device regions 100a in which devices are formed and TSV regions 100b in which TSVs and guard rings are formed. The semiconductor structure 100 includes a device layer 102, a frontside multilayer interconnect (FMLI) structure 110 disposed over the device layer 102, a backside multilayer interconnect (BMLI) structure 112 disposed under the device layer 102, and a carrier wafer (e.g., a silicon wafer) 122 bonded to the FMLI structure 110 such as through a bonding layer 124.

The device layer 102 has a side 104 (e.g., a frontside) and a side 106 (e.g., a backside) that is opposite the side 104. The device layer 102 can include circuitry fabricated on and/or over the side 104 by front end-of-line (FEOL) processing. For example, the device layer 102 can include various device components/features, such as a semiconductor substrate, doped wells (e.g., n-wells and/or p-wells), isolation features (e.g., shallow trench isolation (STI) structures and/or other suitable isolation structures), metal gates (e.g., a metal gate having a gate electrode and a gate dielectric), gate spacers along sidewalls of the metal gate, source/drain features (e.g., epitaxial source/drains), other suitable device components/features, or combinations thereof. In some embodiments, the device layer 102 includes a planar transistor, where a channel of the planar transistor is formed in the semiconductor substrate between respective source/drains and a respective metal gate is disposed on the channel (e.g., on a portion of the semiconductor substrate in which the channel is formed). In some embodiments, the device layer 102 includes a non-planar transistor having a channel formed in a semiconductor fin that extends from the semiconductor substrate and between respective source/drains on/in the semiconductor fin, where a respective metal gate is disposed on and wraps the channel of the semiconductor fin (i.e., the non-planar transistor is a fin-like field effect transistor (FinFET)). In some embodiments, the device layer 102 includes a non-planar transistor having channels formed in semiconductor layers suspended over the semiconductor substrate and extending between respective source/drains, where a respective metal gate is disposed on and surrounds the channels (i.e., the non-planar transistor is a gate-all-around (GAA) transistor). The various transistors of the device layer 102 can be configured as planar transistors and/or non-planar transistors depending on design requirements.

The device layer 102 may include various passive microelectronic devices and active microelectronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide functionally distinct regions of an IC, such as a logic region (i.e., a core region), a memory region, an analog region, a peripheral region (e.g., an input/output (I/O) region), a dummy region, other suitable region, or combinations thereof. The logic region may be configured with standard cells, each of which can provide a logic device and/or a logic function, such as an inverter, an AND gate, an NAND gate, an OR gate, an NOR gate, a NOT gate, an XOR gate, an XNOR gate, other suitable logic device, or combinations thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or combinations thereof. In some embodiments, memory cells and/or logic cells include transistors and interconnect structures that combine to provide storage devices/functions and logic devices/functions, respectively.

FIG. 2A is an enlarged view of a region I of the semiconductor structure 100 of FIG. 1, which includes multiple transistors formed in the device layer 102. In FIG. 2A, the device layer 102 includes a semiconductor substrate 202 and various transistors, such as a transistor T1 and a transistor T2. Transistors T1 and T2 each include a respective gate structure 208 (which can include gate spacers disposed along a gate stack (e.g., a gate electrode disposed over a gate dielectric)) disposed between respective source/drain features 212 (e.g., epitaxial source/drain features), which are disposed on, in, and/or over the semiconductor substrate 202, where a channel extends between respective source/drain features 212 in the semiconductor substrate 202. The device layer 102 may further include isolation structures 214, such as shallow trench isolation (STI) features, that separate and/or electrically isolate transistors from other transistors or devices in the device layer 102. The device layer 102 further includes a dielectric layer 218. The dielectric layer 218 can an interlayer dielectric (ILD) layer and/or a contact etch stop layer (CESL). Disposed above the dielectric layer 218 is a dielectric layer 222, which can similarly include an ILD layer and an etch stop layer (ESL).

Gate contacts (or referred to as gate vias) 232 are disposed in the dielectric layer 222, source/drain contacts 234 are disposed in the dielectric layer 218, and contact vias 236 are disposed in the dielectric layer 222. Gate contacts 232 electrically and physically connect the gate structures 208 (in particular, gate electrodes) to metal lines 240 in a metal zero interconnect layer (M0 level) of a frontside multilayer interconnect (FMLI) structure 110, and the source/drain contacts 234 and the contact vias 436 electrically and physically connect a frontside of the source/drain features 212 to metal lines 240 in the M0 level of the FMLI structure 110. The dielectric layer 222, the gate contacts 232, and the contact vias 236 form a via zero interconnect layer (V0 level) of the FMLI structure 110. On the backside of the device layer 102, a backside dielectric layer 224 is disposed under the semiconductor substrate 202. Backside source/drain contacts 242 extend through the semiconductor substrate 202 and electrically and physically connect a backside of the source/drain contacts 234 to metal lines 244 in the backside metal zero interconnect layer (BM0 level) of a backside multilayer interconnect (BMLI) structure 112. The frontside and backside of the source/drain features 212 may each have a silicide layer 246 in physical contact with the source/drain contacts 234 and backside source/drain contacts 242. The silicide layers 246 reduce contact resistance. The semiconductor substrate 202 and the backside source/drain contacts 242 form the backside via zero interconnect layer (BV0 level) of the BMLI structure 112.

Referring back to FIG. 1, a frontside multilayer interconnect (FMLI) structure 110 is disposed over the device layer 102, and a backside multilayer interconnect (BMLI) structure 112 is disposed under the device layer 102. Each of the FMLI structure 110 and the BMLI structure 112 may include one or more interconnect layers. In the device regions 100a, the FMLI structure 110 and the BMLI structure 112 electrically couple various devices and/or components (such as transistors T1 and T2 depicted in FIG. 2A) of the device layer 102. In the TSV regions 100b, the FMLI structure 110 and a first portion of the BMLI structure 112 form the TSV guard rings 150. In the TSV regions 100b, a second portion of the BMLI structure 112 physically and electrically connects to the TSV 132.

In the depicted embodiment, the FMLI structure 110 includes a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), a metal three interconnect layer (M3 level), and all the way to a via x interconnect layer (Vx level), and a metal x interconnect layer (Mx level), in which x represents an integer (e.g., from 2 to 10).

Each of the V0 level, M0 level, V1 level, M1 level, V2 Level, M2 level, V3 level, M3 level, . . . Vx level, and Mx level may be referred to as a metal level. Metal lines formed at the M0 level may be referred to as M0 metal lines. Similarly, via or metal lines formed at the V1 level, M1 level, V2 level, M2 level, V3 level, M3 level, . . . Vx level, and Mx level may be referred to as V1 vias, M1 metal lines, V2 vias, M2 metal lines, V3 vias, M3 metal lines, . . . Vx vias, Mx metal lines, respectively. Each level of the FMLI structure 110 includes conductive features (e.g., metal lines 116, metal vias 118, and/or metal contacts) disposed in one or more dielectric layers (e.g., an interlayer dielectric (ILD) layer and an etch stop layer (ESL)). The dielectric layers (e.g., the dielectric layer 222 at V0 and M0 level depicted in FIG. 2A) of the FMLI structure 110 are collectively referred to as a dielectric structure 115. In some embodiments, conductive features at a same level of the FMLI structure 110, such as M0 level, are formed simultaneously. In some embodiments, conductive features at a same level of the FMLI structure 110 have top surfaces that are substantially planar with one another and/or bottom surfaces that are substantially planar with one another.

As discussed above in association with FIG. 2A, source/drain contacts may be formed on and in direct contact with silicide layers disposed directly on the source/drain features. The V0 level includes gate contacts disposed on the gate structures and contact vias disposed on the source/drain contacts, where gate contacts connect gate structures to M0 metal lines, contact vias connect source/drain contacts to M0 metal lines. The V1 level includes V1 vias disposed in the dielectric structure 115, where V1 vias connect M0 metal lines to M1 metal lines. M1 level includes M1 metal lines disposed in the dielectric structure 115. V2 level includes V2 vias disposed in the dielectric structure 115, where V2 vias connect M1 metal lines to M2 metal lines. M2 level includes M2 metal lines disposed in the dielectric structure 115. V3 level includes V3 vias disposed in the dielectric structure 115, where V3 vias connect M2 metal lines to M3 metal lines. Similarly, Vx level includes Vx vias disposed in the dielectric structure 115, where Vx vias connect Mx−1 metal lines to Mx metal lines.

In the depicted embodiment, the BMLI structure 112 includes a backside via zero interconnect layer (BV0 level), a backside metal zero interconnect layer (BM0 level), a backside via one interconnect layer (BV1 level), a backside metal one interconnect layer (BM1 level), a backside via two interconnect layer (BV2 level), a backside metal two interconnect layer (BM2 level), and all the way to a backside via y interconnect layer (BVy level), and a backside metal y−1 interconnect layer (My−1 level), in which y represents an integer (e.g., from 2 to 10).

Each of the BV0 level, BM0 level, BV1 level, BM1 level, BV2 Level, BM2 level, . . . BVy level, and BMy level may be referred to as a metal level. Metal lines formed at the BM0 level may be referred to as BM0 metal lines. Similarly, via or metal lines formed at the BV1 level, BM1 level, BV2 level, BM2 level, . . . BVy level, and BMy level may be referred to as BV1 vias, BM1 metal lines, BV2 vias, BM2 metal lines, . . . BVy vias, BMy metal lines, respectively. Each level of the BMLI structure 112 includes conductive features (e.g., metal lines 116′, metal vias 118′, and/or metal contacts) disposed in one or more dielectric layers (e.g., an interlayer dielectric (ILD) layer and an etch stop layer (ESL)). The dielectric layers (e.g., the backside dielectric layer 224 at BM0 level depicted in FIG. 2A) of the BMLI structure 112 are collectively referred to as a dielectric layer (or dielectric structure) 115′. In some embodiments, conductive features at a same level of the BMLI structure 112, such as BM0 level, are formed simultaneously. In some embodiments, conductive features at a same level of the BMLI structure 112 have top surfaces that are substantially planar with one another and/or bottom surfaces that are substantially planar with one another.

As discussed above in association with FIG. 2A, backside source/drain contacts may be formed on and in direct contact with silicide layers disposed directly under the source/drain features. The backside contacts at the BV0 level connect source/drain features to BM0 metal lines. The BV1 level includes BV1 vias disposed in the dielectric structure 115′, where BV1 vias connect BM0 metal lines to BM1 metal lines. BM1 level includes BM1 metal lines disposed in the dielectric structure 115′. BV2 level includes BV2 vias disposed in the dielectric structure 115′, where BV2 vias connect BM1 metal lines to BM2 metal lines. BM2 level includes BM2 metal lines disposed in the dielectric structure 115′. Similarly, BVy level includes BVy vias disposed in the dielectric structure 115, where BVy vias connect My−1 metal lines to BMy metal lines.

In the depicted embodiment, the BMLI structure 112 further includes semiconductor devices 120 disposed under and in electrical connection with the BMy metal lines. In some embodiments, the semiconductor devices 120 may, for example, be configured as DRAM devices, MRAM devices, another suitable memory devices, metal-insulator-metal (MIM) structures (e.g., MIM capacitors), or other semiconductor devices. The present disclosure contemplates the semiconductor devices 120 are disposed between interconnection layers of the BMLI structure 112.

A contact layer 126 is disposed under the BMLI structure 112, and in the depicted embodiment, is disposed under a bottommost metallization layer (e.g., the BMy level) of the BMLI structure 112. The contact layer 126 may include contacts 128 arranged in a desired pattern. Contacts 128 may facilitate electrical connection of the circuitry in the device layer 102 to external circuitry and thus may be referred to as external contacts. In some embodiments, the contacts 128 are under-bump metallization (UBM) structures. In some embodiments, the contacts 128 are redistribution layer (RDL) structures. The contacts 128 may be in physical and electrical contact with the bottom surface of the BMy metal lines. Alternatively, the contacts 128 may be electrically connected to the BMy metal lines through vias. In some embodiments, the contact layer 126 includes at least one passivation layer, such as a passivation layer 130 disposed under the dielectric structure 115′. In such embodiments, the contacts 128 are disposed in the passivation layer 130. The passivation layer 130 may include a material that is different than a dielectric material of the ILD layers in the dielectric structure 115′. In some embodiments, the passivation layer includes polyimide, undoped silicate glass (USG), silicon oxide, silicon nitride, other suitable passivation material, or combinations thereof. In some embodiments, a dielectric constant of a dielectric material of the passivation layer is greater than a dielectric constant of the ILD layers in the dielectric structure 115′. The passivation layer 130 may have a multilayer structure having multiple dielectric materials. For example, the passivation layer 130 can include a silicon nitride layer and a USG layer.

A TSV 132 is disposed in the TSV region 100b. From bottom up, the TSV 132 physically lands on one of the bottom metallization layers of the BMLI structure 112 and extends upwardly through the dielectric structure 115′, the device layer 102, the dielectric structure 115 and partially through the carrier wafer 122. In the depicted embodiment, the TSV 132 physically lands on the BMy−1 (the second to the bottommost) metal line. Further, in the depicted embodiment, the BMy−1 metal line 116′ horizontally extends to a position directly under the guard ring 150. That is, in the depicted embodiment, the guard ring 150 does not extend downwardly into the bottom metallization layers (e.g., BVy−1, BMy−1, BVy, and BMy metal layers). The present disclosure contemplates the TSV 132 physically lands on metal lines 116′ in other metallization layers of the BMLI structure 112, such as the BMy metal line or a BMy-z metal line, in which z is an integer less than y.

FIG. 2B is an enlarged view of a region II of the semiconductor structure 100 of FIG. 1, in which the TSV 132 physically lands on a metal line 116′ located in one of the bottom metallization layers of the BMLI structure 112 that is located in the TSV regions 100b. The TSV 132 and the metal line 116′ in the region II are surrounded by the dielectric structure 115′.

The dielectric structure 115′ includes a dielectric material, such as silicon oxide, tetraethylorthosilicate (TEOS) oxide, phosphosilicate glass (PSG), boron-doped silicate glass (BSG), boron-doped PSG (BPSG), low-k dielectric material (having, for example, a dielectric constant that is less than a dielectric constant of silicon oxide (e.g., k<3.9)), other suitable dielectric material, or combinations thereof. Exemplary low-k dielectric materials include fluorosilicate glass (FSG), carbon-doped oxide, Black Diamond® (Applied Materials of Santa Clara, California), xerogel, aerogel, amorphous fluorinated carbon, parylene, benzocyclobutene (BCB), SiLK (Dow Chemical, Midland, Michigan), polyimide, other low-k dielectric material, or combinations thereof. In some embodiments, the dielectric structure 115′ includes a low-k dielectric material, such as carbon-doped oxide, or an extreme low-k dielectric material (e.g., k≤2.5), such as porous carbon-doped oxide.

The TSV 132 includes a conductive material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. In the depicted embodiment, the TSV 132 includes a bulk metal layer 134 (also referred to as a metal fill layer, a conductive plug, a metal plug, or combinations thereof), a barrier layer 136, and a liner 138. The barrier layer 136 is disposed between the bulk metal layer 134 and the liner 138. The barrier layer 136 can include titanium, titanium alloy (e.g., TiN), tantalum, tantalum alloy (e.g., TaN), other suitable barrier material (e.g., a material that can prevent diffusion of metal constituents from TSV 132 into dielectric structure 115), or combinations thereof. In some embodiments, the bulk metal layer 134 is a copper plug or a tungsten plug, and the barrier layer 136 is a metal nitride layer (e.g., TaN layer or TiN layer). In some embodiments, the bulk metal layer 134 includes a seed layer between the barrier layer 136 and the metal plug. The seed layer can include copper, tungsten, other suitable metals (such as those described herein), alloys thereof, or combinations thereof. In some embodiments, the liner 138 is a dielectric layer between the barrier layer 136 and dielectric structure 115′. The liner 138 includes silicon oxide, silicon nitride, other suitable dielectric material, or combinations thereof. The bulk metal layer 134, the barrier layer 136, the liner 138, or combinations thereof may have a multilayer structure. In some embodiments, the TSV 132 includes polysilicon (e.g., the metal plug is a polysilicon plug).

The metal lines 116′ (as well as metal lines 116, vias 118 and 118′, contacts 128) may include a bulk metal layer (also referred to as a metal fill layer, a conductive plug, a metal plug, or combinations thereof) 140 and a barrier layer 142, in some embodiments. The bulk metal layer 140 may include a conductive material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. The barrier layer 142 may include titanium, titanium alloy (e.g., TiN), tantalum, tantalum alloy (e.g., TaN), other suitable barrier material (e.g., a material that can prevent diffusion of metal constituents from the bulk metal layer 140 into the dielectric structure 115′). In some embodiments, lower metal lines 116′ (as well as lower metal lines 116, vias 118 and 118′), which are closer to the device layer 102, may include tungsten, ruthenium, cobalt, or combinations thereof, while higher metal lines 116′ (as well as lower metal lines 116, vias 118 and 118′), which are further away from the device layer 102 may include different metal material(s), such as copper. In some embodiments, metal lines 116 and 116′, vias 118 and 118′, and contacts 128 include the same metal materials.

Referring back to FIG. 1, a guard ring 150 surrounds the TSV 132 and is spaced apart from the TSV 132. In some embodiments, the guard ring 150 is electrically connected to a voltage. In some embodiments, the guard ring 150 is electrically connected to an electrical ground. In some embodiments, the guard ring 150 is configured to electrically insulate the TSV 132 from the device features in the device regions 100a, including the FMLI structure 110, the BMLI structure 112, and the device layer 102. In some embodiments, the guard ring 150 absorbs thermomechanical stress from, within, and/or around the TSV 132. In some embodiments, the guard ring 150 reduces thermomechanical stress from, within, and/or around the TSV 132. In some embodiments, the guard ring 150 reduces or eliminates cracking and/or delamination in semiconductor structure 100. In some embodiments, the guard ring 150 provides structural support, integrity, reinforcement, or combinations thereof for the TSV 132.

In the depicted embodiment, the guard ring 150 has frontside features disposed in the dielectric structure 115 and backside features disposed in the dielectric structure 115′. The frontside features of the guard ring 150 are formed by the portion of the FMLI structure 110 in the TSV regions 100b. Each layer of the frontside features of the guard ring 150 includes a respective metal line 116 and a respective via 118. The backside features of the guard ring 150 are formed by a first portion of the BMLI structure 112 in the TSV regions 100b. Each layer of the backside features of the guard ring 150 includes a respective metal line 116′ and a respective via 118′. Particularly, the backside features of the guard ring 150 are formed by the portion of the BMLI structure 112 above the metallization layer on which the TSV 132 physically lands on. In the depicted embodiment, the TSV 132 physically lands on the BMy−1 metal lines, and the guard ring 150 starts from the BMy−2 metal lines. In the depicted embodiment, there are no BVy−1 vias in the TSV regions 100b, such that the BMy−2 metal lines of the guard ring 150 have no electrical connection with the BMy−1 metal lines and thus no electrical connection with the TSV 132.

FIG. 2C is an enlarged view of a region III of the semiconductor structure 100 of FIG. 1, in which the guard ring 150 is formed in an active region. The bottom layer of the frontside features of the guard ring 150 (e.g., metal lines 240 in the M0 level and contact vias 236 in the V0 level) are physically and/or electrically connected to the source/drain contacts 234 and the frontside of the source/drain features 212. The top layer of the backside features of the guard ring 150 (e.g., metal lines 244 in the BM0 level and backside source/drain contacts 242) are physically and electrically connected to the backside of the source/drain features 212. Through the source/drain features 212 (and the silicide layers 246 if presented), the frontside features of the guard ring 150 and the backside features of the guard ring 150 are electrically connected.

FIG. 2D is an enlarged view of a region III of the semiconductor structure 100 of FIG. 1 in an alternative embodiment, in which the guard ring 150 is formed in an STI region. Since not like an active region there is no source/drain features presented in an STI region, instead, a via 250 is formed in the device layer 102. The via 250 extends through the semiconductor substrate 202, the STI feature 214, and the dielectric layer 218. The via 250 connects the bottom layer of the frontside features of the guard ring 150 (e.g., metal lines 240 in the M0 level and contact vias 236 in the V0 level) and the backside feature of the guard ring 150 (e.g., metal lines 244 in the BM0 level). The via 250 may include a bulk metal layer and a barrier layer. The bulk metal layer may include a conductive material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. The barrier layer may include titanium, titanium alloy (e.g., TiN), tantalum, tantalum alloy (e.g., TaN), other suitable barrier material. In some embodiments, the via 250, the metal lines 240, the contact vias 236, and the metal lines 244 may include the same metal material. In an alternative embodiment, the via 250 may include a metal material different from the metal lines 240, the contact vias 236, and the metal lines 244.

Reference is now made to FIG. 3, which provides a top view of the guard rings 150 and the corresponding TSVs 132 in various configurations I-VII. One or more of these configurations can be implemented at the same time in the semiconductor structure 100 of FIG. 1 depending on device performance needs. In each of these depicted configurations I-VII, the TSVs 132 exhibit a circular shape when viewed from the top. However, it's worth noting that the TSVs 132 can also take on various other shapes, including squares, rhombuses, trapezoids, hexagons, octagons, or any other suitable shape.

In configuration I, the guard ring 150 encircles the TSV 132 in a continuous circular ring when viewed from above. Alternatively, the guard ring 150 may adopt a discontinuous configuration, composed of discrete segments. Additionally, in some cases, the guard ring 150 may have different shapes. For instance, in configuration II, the guard ring 150 may have the form of a square ring. In configuration III, the guard ring 150 may have the form of an octagonal ring. Configuration IV showcases a double square ring, in which the inner and outer rings are concentric and electrically connected through conductive taps 152 distributed along the opposing edges of both rings.

The guard rings 150 may also share one or more common edges when respective TSVs 132 are adjacent to each other. For example, configuration V illustrates two guard rings 150 sharing a common edge between two neighboring TSVs 132. In configuration VI, four guard rings 150 are arranged in a 2×2 array, with common edges between pairs of adjacent TSVs 132. Moreover, in certain scenarios, multiple TSVs 132 can collectively share a single guard ring 150. For instance, configuration VII displays a single guard ring (150) surrounding four TSVs 132 arranged in a 2×2 array.

In configurations I-VII, the guard ring 150 is separated from the respective TSV 132 by the dielectric structures 115 and 115′ (FIG. 1). In some embodiments, a spacing between the guard ring 150 and the respective TSV 132 is about 0.2 μm to about 0.5 μm to maximize protection and/or shielding provided by the guard ring 150 to the TSV 132. The spacing greater than 0.5 μm is too large and prevents the guard ring 150 from sufficiently protecting the TSV 132. For example, when the guard ring 150 is spaced too far from (e.g., greater than 0.5 μm from) the TSV 132, the guard ring 150 cannot sufficiently absorb and/or reduce stresses from, within, and/or around the TSV 132. Stresses may then undesirably concentrate on the TSV 132, which can degrade performance and/or structural integrity of the TSV 132. Spacing less than 0.2 μm is too small and can result in a physical connection between the guard ring 150 and the TSV 132, which negates a purpose and/or a function of the guard ring 150. For example, when the guard ring 150 is spaced too close to (e.g., less than 0.2 μm from) the TSV 132, the guard ring 150 is essentially an extension of the TSV 132 (and forms a portion thereof) and cannot protect the TSV 132 as intended. For example, the guard ring 150 cannot provide electrical insulation; reduce or eliminate stress from, within, and/or around the TSV 132; reduce or eliminate cracking; provide structural integrity; or combinations thereof.

Reference is now made to FIGS. 4-11, which are fragmentary cross-sectional views of a workpiece 200 at various fabrication stages of forming the TSV 132 and the guard ring 150 as depicted in FIG. 1, according to various aspects of the present disclosure. FIGS. 4-11 have been simplified for the sake of clarity to better understand the inventive concepts of the present disclosure. Additional features can be added in workpiece 200, and some of the features described below can be replaced, modified, or eliminated in other embodiments of workpiece 200.

Turning to FIG. 4, after the workpiece 200 has undergone FEOL processing and MEOL processing, workpiece 200 undergoes BEOL processing to form the FMLI structure 110 over the device regions 100a of the device layer 102. The FMLI structure 110 may be physically and/or electrically connected to semiconductor devices, such as transistors, formed in device regions 100a. The frontside features of the guard ring 150 are also formed over the TSV regions 100b of the device layer 102 while forming the FMLI structure 110. The frontside features of the guard ring 150 may be physically and/or electrically connected to the device layer 102, such as to source/drain features in active regions and/or power vias in STI regions. The guard ring 150 is a conductive ring (e.g., a metal ring) having an inner dimension that defines a dielectric region 210 of dielectric structure 115. As described further below, the TSV 132 is formed to extend through the dielectric region 210.

In some embodiments, depositing the portion of the dielectric structure 115 includes depositing an ILD layer. In some embodiments, depositing the portion of dielectric structure 115 includes depositing a CESL. The dielectric structure 115, CESL, ILD layer, or combinations thereof are formed by chemical vapor deposition (CVD), plasma enhanced CVD (PECVD), high density plasma CVD (HDPCVD), flowable CVD (FCVD), physical vapor deposition (PVD), atomic layer deposition (ALD), metalorganic chemical vapor deposition (MOCVD), remote plasma CVD (RPCVD), low-pressure CVD (LPCVD), atomic layer CVD (ALCVD), atmospheric pressure CVD (APCVD), other suitable deposition methods, or combinations thereof.

In some embodiments, the metal lines 116 and the vias 118 of the FMLI structure 110 and/or the guard ring 150 are formed by a dual damascene process, which can involve depositing conductive material for via/metal line pairs at the same time. In such embodiments, vias 118 and metal lines 116 may share a barrier layer and a conductive plug, instead of each having a respective and distinct barrier layer and conductive plug (e.g., where a barrier layer of a respective metal line 116 separates a conductive plug of the respective metal line 116 from a conductive plug of its corresponding, respective via 118). In some embodiments, the dual damascene process includes performing a patterning process to form interconnect openings that extend through the dielectric structure 115 to expose underlying conductive features. The patterning process can include a first lithography step and a first etch step to form trench openings of the interconnect openings (which correspond with and define metal lines 116) in the dielectric structure 115 and a second lithography step and a second etch step to form via openings of the interconnect openings (which correspond with and define vias 118) in the dielectric structure 115. The first lithography/first etch step and the second lithography/second etch step can be performed in any order (e.g., trench first via last or via first trench last). The first etch step and the second etch step are each configured to selectively remove dielectric structure 115 with respect to a patterned mask layer. The first etch step and the second etch step may be a dry etching process, a wet etching process, other suitable etching process, or combinations thereof.

After performing the patterning process, the dual damascene process can include performing a first deposition process to form a barrier material over dielectric structure 115 that partially fills the interconnect openings and performing a second deposition process to form a bulk conductive material over the barrier material, where the bulk conductive material fills remainders of the interconnect openings. In such embodiments, the barrier material and the bulk conductive material are disposed in the interconnect openings and over a top surface of the dielectric structure 115. The first deposition process and the second deposition process can include CVD, PVD, ALD, HDPCVD, MOCVD, RPCVD, PECVD, LPCVD, ALCVD, APCVD, PEALD, electroplating, electroless plating, other suitable deposition methods, or combinations thereof. A CMP process and/or other planarization process is then performed to remove excess bulk conductive material and barrier material from over the top surface of the dielectric structure 115, resulting in the patterned via layer (e.g., vias 118) and the patterned metal layer (e.g., metal lines 116) of one of the interconnect layers of the FMLI structure 110 and corresponding interconnect structure of the guard ring 150. The CMP process planarizes top surfaces of the dielectric structure 115 and the vias 118 and/or the metal lines 116. The barrier material and the bulk conductive material may fill the trench openings and the via openings of the interconnect openings without interruption, such that barrier layers and conductive plugs of the metal lines 116 and the vias 118 may each extend continuously from the metal lines 116 to respective vias 118 without interruption.

In some embodiments, for a given level interconnect layer, the metal lines 116 and the vias 118 of an interconnect structure of the guard ring 150 at the given level interconnect layer are formed simultaneously with the metal lines 116 and the vias 118, respectively, of the given level interconnect layer. In some embodiments, for a given level interconnect layer, the metal lines 116 and the vias 118 of an interconnect structure of the guard ring 150 at the given level interconnect layer are formed at least partially simultaneously with the metal lines 116 and the vias 118, respectively, of the given level interconnect layer. In some embodiments, for a given level interconnect layer, the metal lines 116 and the vias 118 of an interconnect structure of the guard ring 150 at the given level interconnect layer are formed by different processes than the metal lines 116 and the vias 118, respectively, of the given level interconnect layer. In some embodiments, for a given level interconnect layer, the metal lines 116 and/or the vias 118 of an interconnect structure of the guard ring 150 at the given level interconnect layer and the metal lines 116 and/or the vias 118, respectively, of the given level interconnect layer are formed by the same single damascene process. In some embodiments, for a given level interconnect layer, the metal lines 116 and/or the vias 118 of an interconnect structure of the guard ring 150 at the given level interconnect layer and the metal lines 116 and/or the vias 118, respectively, of the given level interconnect layer are formed by different single damascene processes. In some embodiments, for a given level interconnect layer, the metal lines 116 and the vias 118 of an interconnect structure of the guard ring 150 at the given level interconnect layer and the metal lines 116 and the vias 118 of the given level interconnect layer are formed by the same dual damascene process. In some embodiments, for a given level interconnect layer, the metal lines 116 and the vias 118 of an interconnect structure of the guard ring 150 at the given level interconnect layer and the metal lines 116 and the vias 118 of the given level interconnect layer are formed by different dual damascene processes.

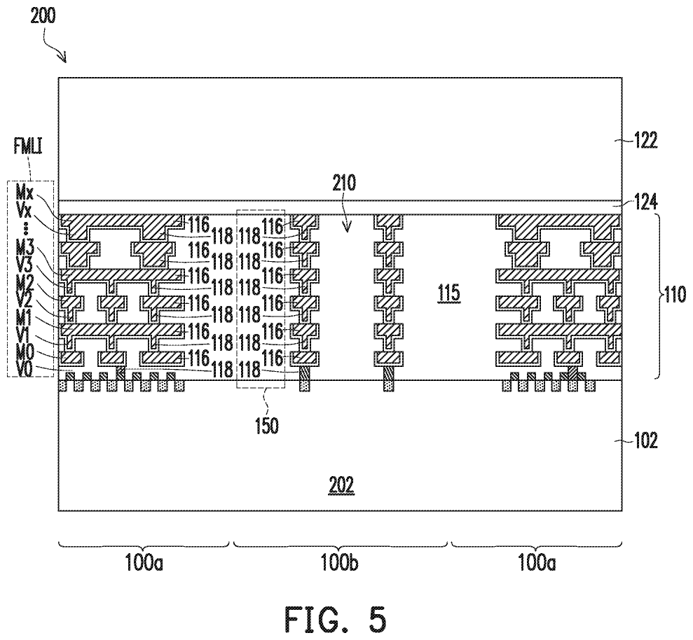

Referring to FIG. 5, the frontside of the workpiece 200 is attached to a carrier 122, which allows the workpiece 200 to be flipped upside down. This makes the workpiece 200 accessible from the backside of the workpiece 200 for further processing. The carrier 122 may be attached to the workpiece 200 with any suitable attaching processes, such as direct bonding, hybrid bonding, using adhesive, or other bonding methods. In the depicted embodiment, a bonding layer 124 is applied between the top surface of the workpiece 200 and the carrier 122. The bonding process may further include alignment, annealing, and/or other processes. The carrier 122 may be a silicon wafer in some embodiments and also referred to as the carrier wafer 122.

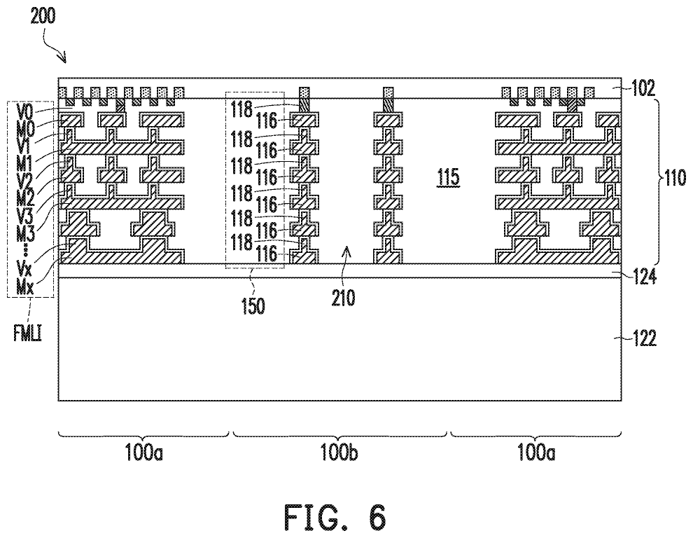

Referring to FIG. 6, the workpiece 200 is thinned down from the the backside of the workpiece 200, such that a majority portion of the semiconductor substrate 202 of the device layer 102 is removed. The thinning process may include a mechanical grinding process and/or a chemical thinning process. A substantial amount of semiconductor substrate 202 may be first removed from the device layer 102 during a mechanical grinding process. Afterwards, a chemical thinning process may apply an etching chemical to the backside of the semiconductor substrate 202 to further thin down the semiconductor substrate 202.

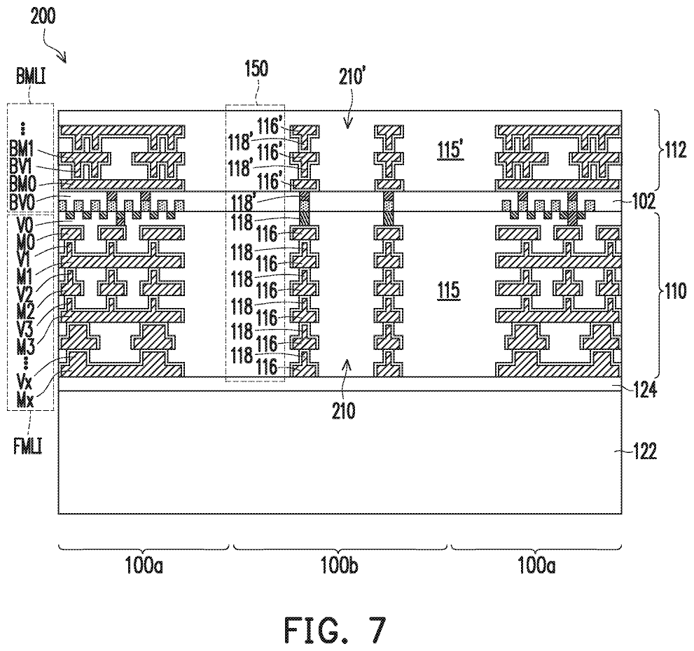

Referring to FIG. 7, a first portion of the BMLI structure 112 is formed over the backside of the workpiece 200. The BMLI structure 112 may be physically and/or electrically connected to semiconductor devices, such as transistors, formed in device regions 100a. The backside features of the guard ring 150 are also formed over the TSV regions 100b of the device layer 102 while forming the BMLI structure 112. The backside features of the guard ring 150 may be physically and/or electrically connected to the device layer 102, such as to source/drain features in active regions and/or power vias in STI regions. The guard ring 150 is a conductive ring (e.g., a metal ring) having an inner dimension that defines a dielectric region 210′ of the dielectric structure 115′. As described further below, the TSV 132 is formed to extend through the dielectric region 210′. The formation of the dielectric structure 115′, the metal lines 116′, and the vias 118′ of the BMLI structure 112 and/or the guard ring 150 are similar to the formation of the dielectric structure 115, the metal lines 116, and the vias 118′ described above in association with FIG. 4, which is omitted herein for the sake of simplicity. Notably, in FIG. 7, an ILD layer of the dielectric structure 115 corresponding to a backside via layer is deposited as the bottommost layer of the BMLI structure 112 without forming vias therein.

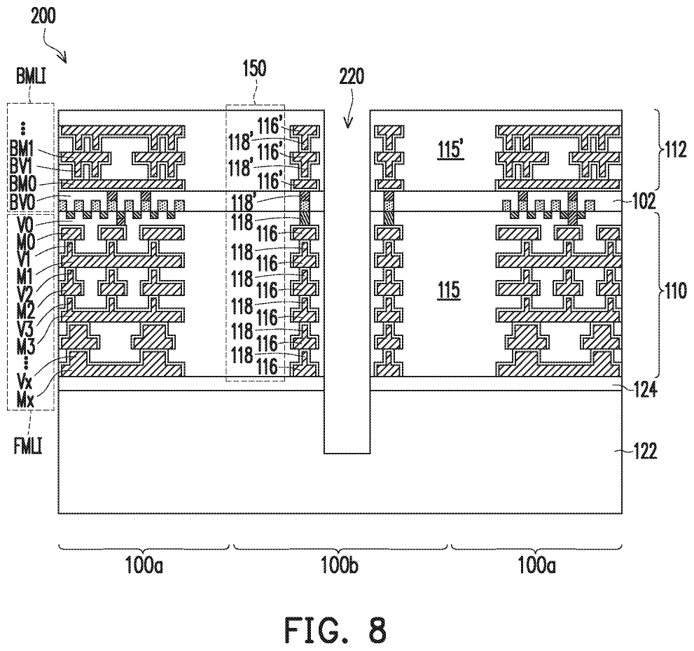

Referring to FIG. 8, a trench 220 is formed in the dielectric region 210′ of the dielectric structure 115′ and the dielectric region 210 of the dielectric structure 115. The trench 220 extends through the dielectric structure 115′, the device layer 102, and the dielectric structure 115, and partially into the carrier wafer 122. In some embodiments, forming the trench 220 includes forming a patterned mask layer having an opening therein that exposes the dielectric region 210′ of the dielectric structure 115′ and etching the dielectric structure 115′ and subsequently the device layer 102 and the dielectric structure 115 using the patterned mask layer as an etch mask. The patterned mask layer may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer is a patterned hard mask layer (e.g., a silicon nitride layer). In some embodiments, the patterned mask layer is a patterned resist layer. The etching may be a dry etching process, a wet etching process, other etching process, or combinations thereof. In some embodiments, the etching process is an isotropic dry etch. In some embodiments, a Bosch process, is implemented to extend the trench 220 through the dielectric structure 115′, the device layer 102, the dielectric structure 115, and partially into the carrier wafer 122. A Bosch process generally refers to a high-aspect ratio plasma etching process that involves alternating etch phases and deposition phases, where a cycle includes an etch phase and a deposition phase and the cycle is repeated until the trench 220 has a desired depth.

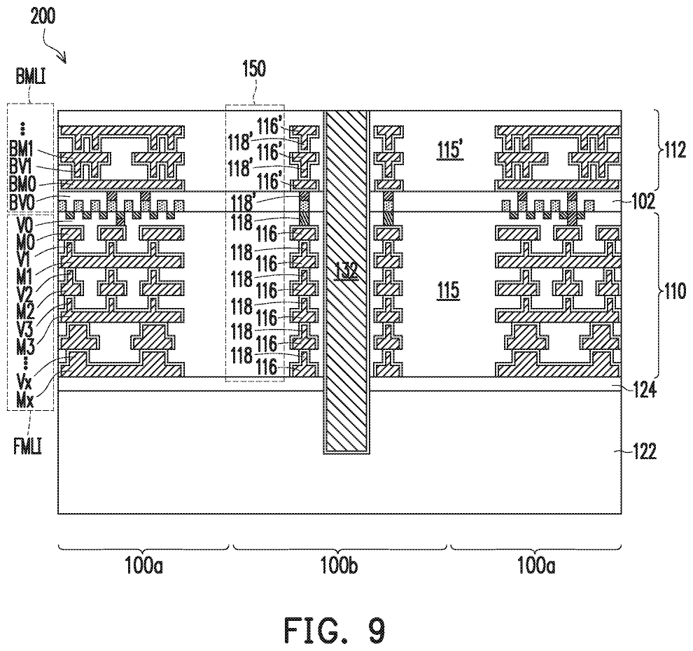

In FIG. 9, fabrication proceeds with filling the trench 220 with the TSV 132. The TSV 132 includes a conductive plug disposed over a barrier layer and a liner. In some embodiments, the TSV 132 is formed by depositing a liner (e.g., silicon oxide, silicon nitride) and a barrier material (e.g., TiN or TaN) over the workpiece 200 that partially fills the trench 220, depositing a bulk conductive material (e.g., Cu) over the workpiece 200 that fills a remainder of the trench 220, and performing a planarization process (e.g., CMP) to remove excess barrier layer material and excess bulk conductive material from over workpiece 200 (e.g., from over a top surface of dielectric structure 115′).

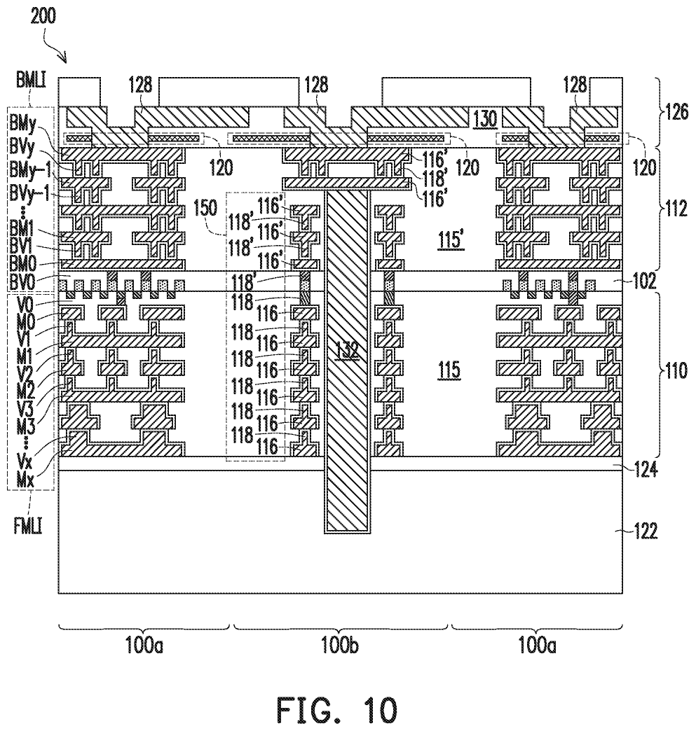

In FIG. 10, the second portion of the BMLI structure 112 is formed over the backside of the workpiece 200 with metal layers disposed in a dielectric layer added to the dielectric structure 115′. The newly added dielectric layer of the second portion of the BMLI structure 112 can be considered as an extension of the dielectric structure 115′ in the vertical direction. Thus, in the device regions 100a, the BVy−1 vias, BMy−1 metal lines, BVy vias, and BMy metal lines are formed in the dielectric structure 115′, such that first and second portions of the BMLI structure 112 are physically and electrically connected. As a comparison, the TSV region 100b is free of the BVy−1 vias. Otherwise, the guard ring 150 would short to the TSV 132 through the BMy−1 metal line. In the TSV region 100b, the BMy−1 meal line, BVy vias, and BMy metal line are formed above the TSV 132. The BMy−1 metal lines are physically and electrically connected to the TSV 132. In the depicted embodiment, the TSV 132 physically contacts the BMy−1 metal line. The present disclosure contemplates the TSV 132 physically contacts a metal line 116′ in other metallization layers of the BMLI structure 112, such as the BMy metal line or a BMy−z metal line, in which z is an integer less than y.

Still referring to FIG. 10, the semiconductor devices 120 are disposed over and in electrical connection with the BMy metal lines. In some embodiments, the semiconductor devices 120 may, for example, be configured as DRAM devices, MRAM devices, another suitable memory devices, metal-insulator-metal (MIM) structures (e.g., MIM capacitors), or other semiconductor devices. The present disclosure contemplates the semiconductor devices 120 are disposed between interconnection layers of the BMLI structure 112. The contact layer 126 is disposed under the BMLI structure 112. The contact layer 126 includes contacts 128 that facilitate electrical connection of the circuitry in the device layer 102 to external circuitry. In some embodiments, the contacts 128 are under-bump metallization (UBM) structures. In some embodiments, the contacts 128 are redistribution layer (RDL) structures. The contacts 128 may be in physical and electrical contact with the bottom surface of the BMy metal lines. Alternatively, the contacts 128 may be electrically connected to the BMy metal lines through vias. In some embodiments, the contact layer 126 includes at least one passivation layer, such as a passivation layer 130 disposed under the dielectric structure 115′. In such embodiments, the contacts 128 are disposed in the passivation layer 130. The passivation layer 130 may include a material that is different than a dielectric material of the ILD layers in the dielectric structure 115′. In some embodiments, the passivation layer includes polyimide, undoped silicate glass (USG), silicon oxide, silicon nitride, other suitable passivation material, or combinations thereof.

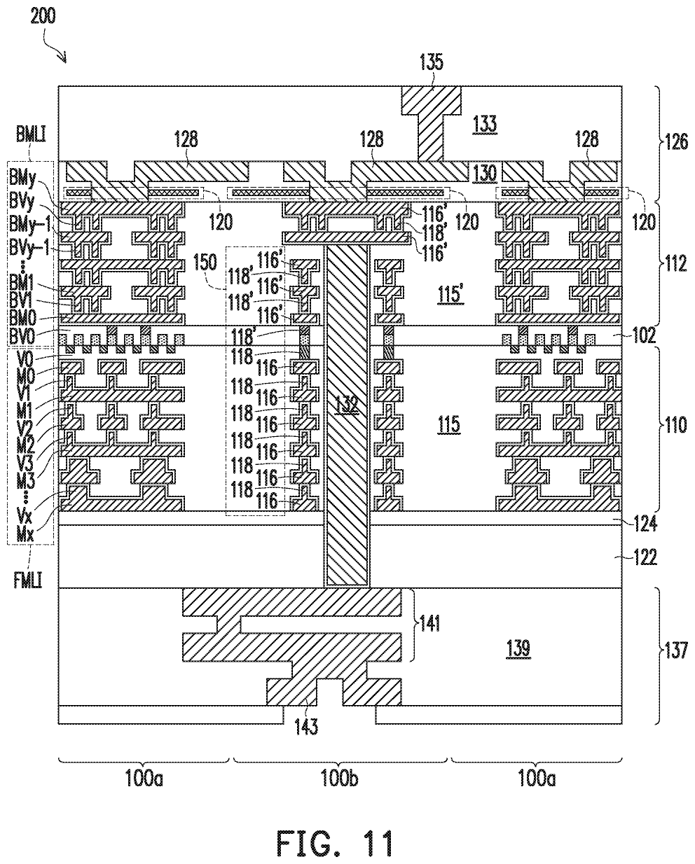

In FIG. 11, fabrication proceeds with forming an ILD layer 133 over the contacts 128 and forming one or more bondpads 135 in the ILD layer 133. The bondpad 135 electrically connects to the TSV 132 through the respective contact 128. A planarization process (e.g., CMP) is performed to remove excess material of the carrier wafer 122 and expose the TSV 132 from the frontside of the workpiece 200. A contact layer 137 is also formed on the frontside of the workpiece 200 after the carrier wafer 122 is thinned and the TSV 132 is exposed. The contact layer 137 includes an interconnect structure 141 formed in a dielectric structure 139. The formation of the dielectric structure 139 may be similar to the dielectric structures 115 and 115′. In some embodiments, depositing the portion of the dielectric structure 139 includes depositing an ILD layer. In some embodiments, depositing the portion of dielectric structure 139 includes depositing a CESL. The interconnect structure 141 includes various conductive features distributed in multiple metal layers, which includes various metal lines for horizontal routing and vias for vertical routing. The contact layer 137 may further include contacts 143 arranged in a desired pattern. The contacts 143 may facilitate electrical connection of the circuitry in the device layer 102 to external circuitry and thus may be referred to as external contacts. In some embodiments, the contacts 143 are under-bump metallization (UBM) structures. In some embodiments, the contacts 143 are redistribution layer (RDL) structures.

The semiconductor structure 100 may be attached (bonded) to another semiconductor structure to form an IC package or portion thereof. For example, in FIGS. 12-17, the semiconductor structure 100 is attached to a semiconductor structure 180, which may be similar to semiconductor structure 100. For example, as depicted FIG. 12, the semiconductor structure 180 includes a respective device layer 102′, a respective FMLI structure 110′ disposed over frontside of the respective device layer 102′, and a respective contact layer 126′ disposed over the respective FMLI structure 110′, which are similar to the respective counterparts in the semiconductor structure 100. In such embodiments, circuitry (e.g., transistors) formed in the device layer 102′ of the semiconductor structure 180 electrically couples to the contacts 143 in the contact layer 137 at the frontside of the semiconductor structure 180 with an electrical routing through the FMLI structure 110′, the contact layer 126′, the contact layer 126, the BMLI structure 112, the TSV 132, and the contact layer 137. The semiconductor structure 100 and the semiconductor structure 180 may be attached by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or combinations thereof.

In some embodiments, the semiconductor structure 100 and the semiconductor structure 180 are chips that include at least one functional IC, such as an IC configured to perform a logic function, a memory function, a digital function, an analog function, a mixed signal function, a radio frequency (RF) function, an input/output (I/O) function, a communications function, a power management function, other function, or combinations thereof. In such embodiments, TSV 132 physically and/or electrically connects chips. In some embodiments, semiconductor structure 100 and semiconductor structure 180 are chips having the same function (e.g., central processing unit (CPU), graphic processing unit (GPU), or memory). In some embodiments, semiconductor structure 100 and semiconductor structure 180 are chips having different functions (e.g., CPU and GPU, respectively). In some embodiments, semiconductor structure 100 and semiconductor structure 180 are system-on-chips (SoCs). In such embodiments, TSV 132 physically and/or electrically connects SoCs. SoC generally refers to a single chip or monolithic die having multiple functions (e.g., CPU, GPU, memory, other functions, or combinations thereof). In some embodiments, the SoC is a single chip having an entire system, such as a computer system, fabricated thereon. In some embodiments, semiconductor structure 100 is a chip and semiconductor structure 180 is an SoC, or vice versa. In such embodiments, TSV 132 physically and/or electrically connects a chip and an SoC.

In some embodiments, the semiconductor structure 100 is a portion of a chip-on-wafer-on-substrate (CoWoS) package, an integrated-fan-out (InFO) package, a system on integrated chip (SoIC) package, other three-dimensional integrated circuit (3DIC) package, or a hybrid package that implements a combination of multichip packaging technologies. In some embodiments, the TSV 132 of semiconductor structure 100 is physically and/or electrically connected to a package substrate, an interposer, a redistribution layer (RDL), a printed circuit board (PCB), a printed wiring board, other packaging structure and/or substrate, or combinations thereof. In some embodiments, the TSV 132 of semiconductor structure 100 is physically and/or electrically connected to controlled collapse chip connections (C4 bonds) (e.g., solder bumps and/or solder balls) and/or microbumps (also referred to as microbonds, μbumps, and/or μbonds), which are physically and/or electrically connected to a packaging structure.

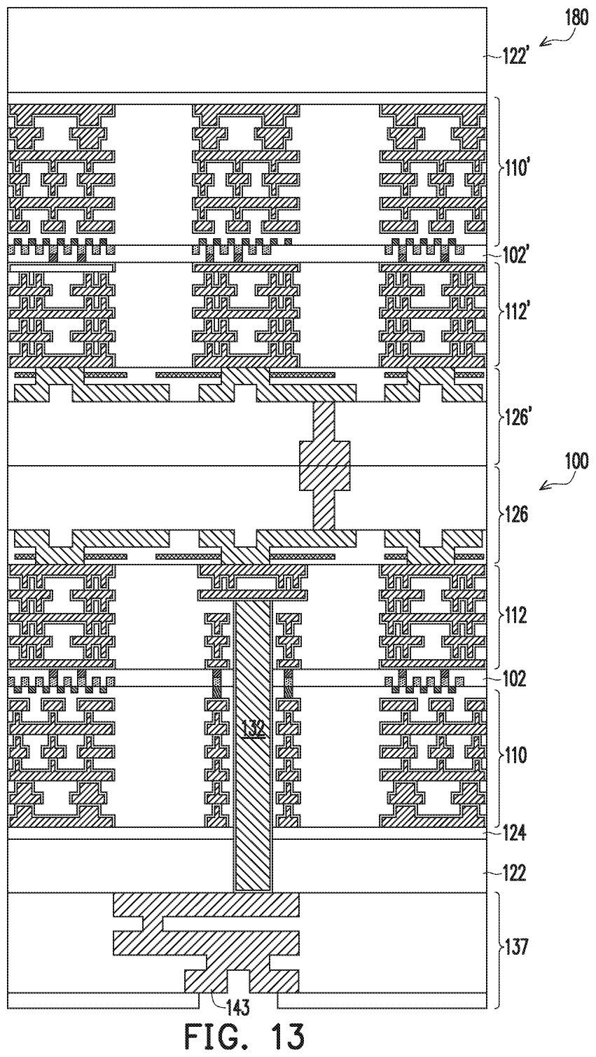

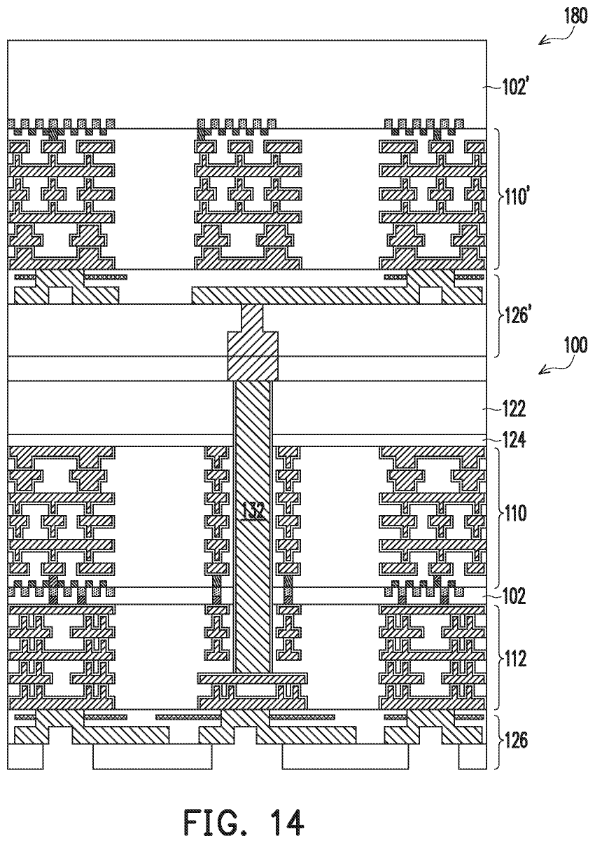

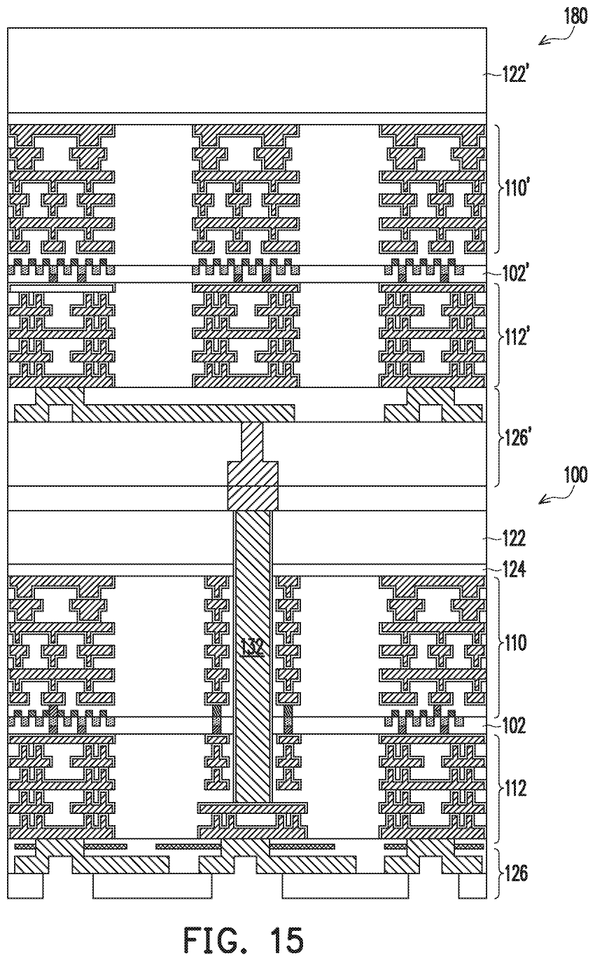

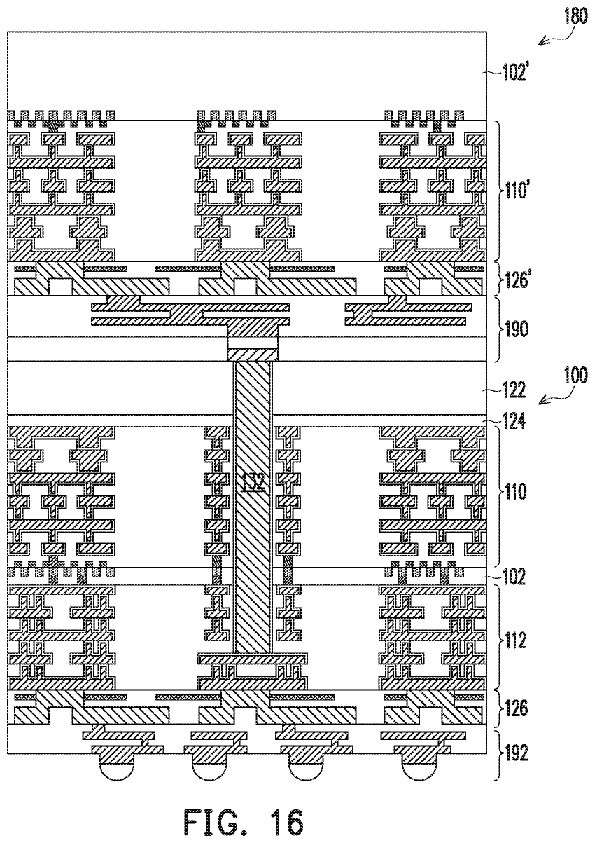

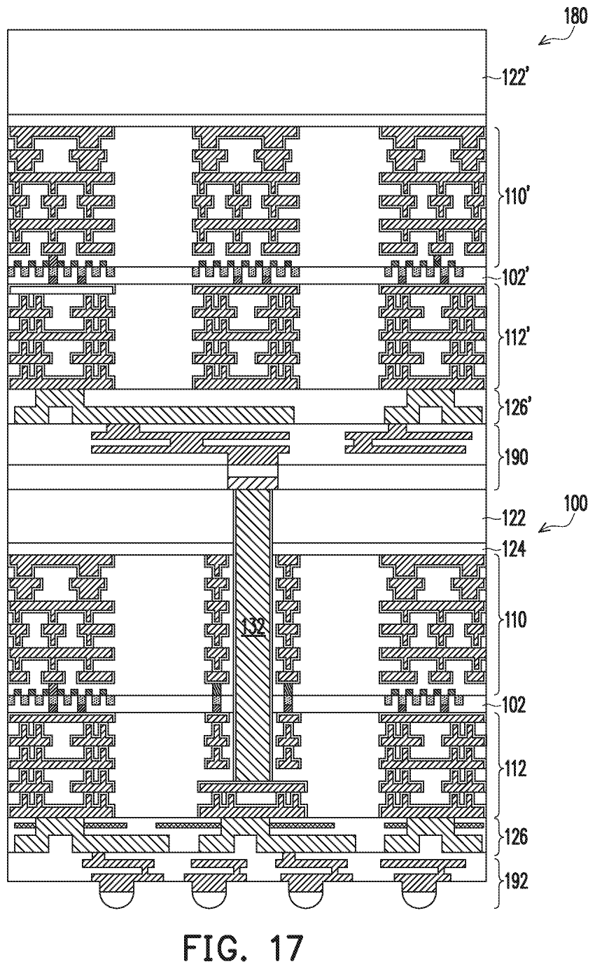

Many aspects of the embodiments in FIGS. 13-17 are the same as or similar to those as depicted in FIG. 12. of the device 100A. The similar aspects are not repeated below in the interest of conciseness. Referring to FIG. 13, the semiconductor structure 180 includes a respective FMLI structure 110′ and a respective BMLI structure 112′. The contact layer 126′ is disposed under the BMLI structure 112′. A carrier wafer 122′ is disposed on the FMLI structure 110′. It is the backside of the semiconductor structure 180 bonded to the backside of the semiconductor structure 100. Referring to FIG. 14, the semiconductor structure 180 includes a respective device layer 102′, a respective FMLI structure 110′ disposed over frontside of the respective device layer 102′, and a respective contact layer 126′ disposed over the respective FMLI structure 110. It is the frontside of the semiconductor structure 180 bonded to the frontside of the semiconductor structure 100. Referring to FIG. 15, the semiconductor structure 180 includes a respective FMLI structure 110′ and a respective BMLI structure 112′. The contact layer 126′ is disposed under the BMLI structure 112′. A carrier wafer 122′ is disposed on the FMLI structure 110′. It is the backside of the semiconductor structure 180 bonded to the frontside of the semiconductor structure 100. Referring to FIG. 16, the semiconductor structure 180 includes a respective device layer 102′, a respective FMLI structure 110′ disposed over frontside of the respective device layer 102′, and a respective contact layer 126′ disposed over the respective FMLI structure 110′. A redistribution layer 190 fans out the contacts at the frontside of the semiconductor structure 180 and interconnects the frontside of the semiconductor structure 180 to the frontside of the semiconductor structure 100. Similarly, a redistribution layer 192 fans out the contacts at the backside of the semiconductor structure 100. The package depicted in FIG. 16 is also referred to as an integrated-fan-out (InFO) package. Referring to FIG. 17, the semiconductor structure 180 includes a respective FMLI structure 110′ and a respective BMLI structure 112′. The contact layer 126′ is disposed under the BMLI structure 112′. A carrier wafer 122′ is disposed on the FMLI structure 110′. A redistribution layer 190 fans out the contacts at the backside of the semiconductor structure 180 and interconnects the backside of the semiconductor structure 180 to the frontside of the semiconductor structure 100. Similarly, a redistribution layer 192 fans out the contacts at the backside of the semiconductor structure 100. The package depicted in FIG. 17 is also referred to as an integrated-fan-out (InFO) package.

The present disclosure provides for many different embodiments. An exemplary semiconductor structure includes a device layer having a frontside and a backside. An FMLI structure is disposed over the frontside of the device layer, a BMLI structure is disposed under the backside of the device layer. A through via extends through the FMLI structure and a first portion of the BMLI structure and is in electrical connection with a second portion of the BMLI structure. The though via may electrically couple power or signal from another semiconductor structure that is attached to the semiconductor structure.

In one example aspect, the present disclosure provides an embodiment of a method of manufacturing a semiconductor device. The method includes forming a first multilayer interconnect structure over a first side of a device layer. The first multilayer interconnect structure includes patterned first metal layers disposed in a first dielectric layer, the device layer has a second side opposite the first side. The method also includes forming a first portion of a second multilayer interconnect structure under the second side of the device layer. The first portion of the second multilayer interconnect structure includes patterned second metal layers disposed in a second dielectric layer. The method also includes forming a trench that extends through the second dielectric layer, the device layer, and the first dielectric layer, forming a conductive structure in the trench, and forming a second portion of the second multilayer interconnect structure under the first portion of the second multilayer interconnect structure. The second portion of the second multilayer interconnect structure includes patterned third metal layers disposed in a third dielectric layer, and one or more of the patterned third metal layers are in electrical connection with the conductive structure. In some embodiments, the forming of the second portion of the second multilayer interconnect structure is after the forming of the conductive structure. In some embodiments, the one or more of the patterned third metal layers include a metal line in physical contact with the conductive structure. In some embodiments, the method also includes prior to the forming of the first portion of the second multilayer interconnect structure, attaching a carrier to the semiconductor device, the carrier being facing the first side of the device layer, and flipping the semiconductor device. In some embodiments, the forming of the trench includes extending the trench partially into the carrier. In some embodiments, the method also includes prior to the forming of the first portion of the second multilayer interconnect structure, thinning the device layer from the second side. In some embodiments, the method also includes forming a first stack of interconnect structures while forming the first multilayer interconnect structure. The first stack of interconnect structures forms a first ring that defines a region of the first dielectric layer and the trench is formed in and extends through the region of the first dielectric layer. In some embodiments, the method also includes forming a second stack of interconnect structures while forming the first portion of the second multilayer interconnect structure. The second stack of interconnect structures forms a second ring that defines a region of the second dielectric layer, and the trench is formed in and extends through the region of the second dielectric layer. In some embodiments, the first stack of interconnect structures and the second stack of interconnect structures are electrically connected through one or more source/drain features formed in the device layer. In some embodiments, the first stack of interconnect structures and the second stack of interconnect structures are electrically connected through one or more vias formed in an isolation region of the device layer.

In another example aspect, the present disclosure provides an embodiment of a method that includes receiving a first workpiece including a device layer, depositing a first dielectric layer on a frontside of the device layer, forming a front portion of a guard ring in the first dielectric layer, depositing a second dielectric layer on a backside of the device layer, forming a back portion of the guard ring in the second dielectric layer, forming a trench extending through a portion of the first dielectric layer encircled by the front portion of the guard ring and a portion of the second dielectric layer encircled by the back portion of the guard ring, forming a through via in the trench, forming one or more metal layers in the second dielectric layer. The one or more metal layers are under the through via and in electrical connection with the through via. The method also includes bonding a second workpiece to the first workpiece. The through via is in electrical connection with conductive features formed in the second workpiece. In some embodiments, after the bonding the second workpiece is facing the frontside of the device layer. In some embodiments, after the bonding the second workpiece is facing the backside of the device layer. In some embodiments, the through via couples power to the second workpiece. In some embodiments, the through via couples signal to the second workpiece. In some embodiments, the guard ring is spaced from the through via for a distance between about 0.2 um and about 0.5 um. In some embodiments, the method also includes attaching a carrier wafer to the first dielectric layer, the through via extending partially through the carrier wafer, and prior to the bonding, thinning the carrier wafer to expose the through via.

In yet another example aspect, the present disclosure provides an embodiment of a semiconductor structure. The semiconductor structure includes a device layer having a first side and a second side, a first dielectric layer disposed over the first side of the device layer, a second dielectric layer disposed under the second side of the device layer, a guard ring with a front portion disposed in the first dielectric layer and a back portion disposed in the second dielectric layer, a metal line disposed in the second dielectric layer under the back portion of the guard ring, and a through via extending through the first dielectric layer and the device layer and in physical contact with the metal line. In some embodiments, the metal line is directly under the back portion of the guard ring. In some embodiments, the semiconductor structure further includes a redistribution layer disposed under the metal line. The redistribution layer includes conductive features in electrical connection with the through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a first multilayer interconnect structure over a first side of a device layer, wherein the first multilayer interconnect structure includes patterned first metal layers disposed in a first dielectric layer, the device layer has a second side opposite the first side;
forming a first portion of a second multilayer interconnect structure under the second side of the device layer, wherein the first portion of the second multilayer interconnect structure includes patterned second metal layers disposed in a second dielectric layer;
forming a trench that extends through the second dielectric layer, the device layer, and the first dielectric layer;
forming a conductive structure in the trench; and
forming a second portion of the second multilayer interconnect structure under the first portion of the second multilayer interconnect structure, wherein the second portion of the second multilayer interconnect structure includes patterned third metal layers disposed in a third dielectric layer, and wherein one or more of the patterned third metal layers are in electrical connection with the conductive structure.

2. The method of claim 1, wherein the forming of the second portion of the second multilayer interconnect structure is after the forming of the conductive structure.

3. The method of claim 1, wherein the one or more of the patterned third metal layers include a metal line in physical contact with the conductive structure.

4. The method of claim 1, further comprising:
prior to the forming of the first portion of the second multilayer interconnect structure, attaching a carrier to the semiconductor device, wherein the carrier is facing the first side of the device layer; and
flipping the semiconductor device.

5. The method of claim 4, wherein the forming of the trench includes extending the trench partially into the carrier.

6. The method of claim 1, further comprising:
prior to the forming of the first portion of the second multilayer interconnect structure, thinning the device layer from the second side.

7. The method of claim 1, further comprising:
forming a first stack of interconnect structures while forming the first multilayer interconnect structure, wherein the first stack of interconnect structures forms a first ring that defines a region of the first dielectric layer, and wherein the trench is formed in and extends through the region of the first dielectric layer.

8. The method of claim 7, further comprising:
forming a second stack of interconnect structures while forming the first portion of the second multilayer interconnect structure, wherein the second stack of interconnect structures forms a second ring that defines a region of the second dielectric layer, and wherein the trench is formed in and extends through the region of the second dielectric layer.

9. The method of claim 8, wherein the first stack of interconnect structures and the second stack of interconnect structures are electrically connected through one or more source/drain features formed in the device layer.

10. The method of claim 8, wherein the first stack of interconnect structures and the second stack of interconnect structures are electrically connected through one or more vias formed in an isolation region of the device layer.

11. A method, comprising:
receiving a first workpiece including a device layer;
depositing a first dielectric layer on a frontside of the device layer;
forming a front portion of a guard ring in the first dielectric layer;
depositing a second dielectric layer on a backside of the device layer;
forming a back portion of the guard ring in the second dielectric layer;
forming a trench extending through a portion of the first dielectric layer encircled by the front portion of the guard ring and a portion of the second dielectric layer encircled by the back portion of the guard ring;
forming a through via in the trench;
forming one or more metal layers in the second dielectric layer, wherein the one or more metal layers are under the through via and in electrical connection with the through via; and
bonding a second workpiece to the first workpiece, wherein the through via is in electrical connection with conductive features formed in the second workpiece.

12. The method of claim 11, wherein after the bonding the second workpiece is facing the frontside of the device layer.

13. The method of claim 11, wherein after the bonding the second workpiece is facing the backside of the device layer.

14. The method of claim 11, wherein the through via couples power to the second workpiece.

15. The method of claim 11, wherein the through via couples signal to the second workpiece.

16. The method of claim 11, wherein the guard ring is spaced from the through via for a distance between about 0.2 um and about 0.5 um.

17. The method of claim 11, further comprising:
attaching a carrier wafer to the first dielectric layer, wherein the through via extends partially through the carrier wafer; and
prior to the bonding, thinning the carrier wafer to expose the through via.

18. A semiconductor structure, comprising:
a device layer having a first side and a second side;
a first dielectric layer disposed over the first side of the device layer;
a second dielectric layer disposed under the second side of the device layer;
a guard ring with a front portion disposed in the first dielectric layer and a back portion disposed in the second dielectric layer;
a metal line disposed in the second dielectric layer under the back portion of the guard ring; and
a through via extending through the first dielectric layer and the device layer and in physical contact with the metal line.

19. The semiconductor structure of claim 18, wherein the metal line is directly under the back portion of the guard ring.

20. The semiconductor structure of claim 19, further comprising:
a redistribution layer disposed under the metal line, wherein the redistribution layer includes conductive features in electrical connection with the through via.
